(19) United States
(12) Patent Application Publication
(10) Pub. No.: US 2014/0254103 A1
(43) Pub. Date: Sep. 11, 2014

(54) ELECTRONIC CONTROL UNIT

(71) Applicant: DENSO CORPORATION, Kariya-city (JP)

(72) Inventors: Tomoaki YOSHIMI, Kariya-city (JP); Shinsuke Oota, Kariya-city (JP)

(73) Assignee: DENSO CORPORATION, Kariya-city (JP)

(21) Appl. No.: 14/190,682

(22) Filed: Feb. 26, 2014

(30) Foreign Application Priority Data
Mar. 6, 2013 (JP) 2013-44091
Sep. 13, 2013 (JP) 2013-190516

(51) Int. Cl. H05K 7/20

(52) U.S. Cl. CPC H05K 7/2089
USPC 361/719

(57) ABSTRACT

A substrate of an electronic control unit has a control region on which a control component is disposed and a power region on which a power component is disposed. Substrate-fixing portions of a housing project from a bottom portion, and the substrate is fixed to the substrate-fixing portions. A heat radiating portion extends from the bottom portion. Semiconductor modules are fixed to a first outer surface and a second outer surface of the heat radiating portion, the first outer surface being on a side opposite to the power component. The heat radiating portion is located between the semiconductor modules and the power component. Therefore, heat interference between the semiconductor modules and the power component is reduced, and a heat radiation performance improves.

### CROSS-REFERENCE TO RELATED APPLICATION

This application is based on Japanese Patent Applications No. 2013-44091 filed on Mar. 6, 2013 and No. 2013-190516 filed on Sep. 13, 2013, the disclosures of which are incorporated herein by reference.

### TECHNICAL FIELD

The present disclosure relates to an electronic control unit.

### BACKGROUND

In recent years, control of motors for vehicles has progressed, and thus the number of motors and the number of electronic control units for controlling the motors have been increased. Moreover, the number of components installed in vehicles has been increased in accordance with the increase in functions of the vehicles, such as functions for safety travelling. On the other hand, it has been tried to increase an interior space so as to provide a comfortable space for users. Therefore, it is important to reduce the size of the electronic control units.

For example, an electronic control unit used for an electric power steering system is arranged in an engine compartment or the back of an instrument panel. In fact, the electronic control unit for the electric power steering system needs to drive a motor with a large amount of current (for example, approximately 80 A). Therefore, the components of the electronic control unit, such as semiconductor modules having a switching function, generate a large amount of heat. In order to reduce the amount of heat generated from the components, it is necessary to increase the size of the electronic component or to use a high-spec component, which is generally expensive. On the other hand, in order to reduce the size and costs of the electronic control unit, a high heat radiation structure is required.

For example, in JP-A-2003-309384 (hereinafter referred to as the patent document 1), an inclined surface is formed so that a distance from a printed board gradually increases, and a switching transistor is arranged on this inclined surface. In the patent document 1, since the switching transistor is arranged so that a lead of the switching transistor is positioned at a top side adjacent to the printed board, the length of the lead can be reduced. With this structure, a resistance of the lead can be reduced, and thus the amount of heat generated can be reduced.

### SUMMARY

In the patent document 1, the switching transistor is arranged to oppose components, such as a power source smoothing capacitor, a coil, and a relay, which generate a relatively large amount of heat. When a large amount of current flows in a state where the switching transistor and the components are opposed to each other as in the patent document 1, there is a fear that the temperature further increases due to heat interference between the components, in addition to the temperature increase due to heat generated from each component.

The present disclosure is made in view of the foregoing issues, and it is an object of the present disclosure to provide an electronic control unit having a high heat radiation structure.

According to an aspect of the present disclosure, an electronic control unit includes a substrate, a control component, a power component, a housing and a plurality of semiconductor modules. The substrate has a control region and a power region. The control component is disposed on the control region of the substrate. The power component is disposed on the power region of the substrate. The housing has a bottom portion that is opposed to the substrate, a substrate-fixing portion, and a heat radiating portion. The substrate-fixing portion extends from the bottom portion, and the substrate is fixed to the substrate-fixing portion. The heat radiating portion extends from the bottom portion. The semiconductor modules are disposed along the heat radiating portion, and are electrically connected to the power region of the substrate. At least one of the semiconductor modules is disposed to a first surface of the heat radiating portion, which is on a side opposite to the power component.

In the structure described above, the power component and the semiconductor modules, which generate a relatively large amount of heat, are located in or adjacent to the power region of the substrate. The control component, which generates a relatively small amount of heat, is disposed in the control region of the substrate.

Examples of the power component are a capacitor, a coil, a resistor and a relay. Examples of the control component are an IC and a CPU.

In the structure, since the control component is spatially spaced from the power component and the semiconductor modules, heat generated from the power component and the semiconductor modules is not easily transferred to the control component.

Further, at least one of the semiconductor modules is disposed on the first surface of the heat radiating portion, the first surface being on a side opposite to the power component. That is, the heat radiating portion is located between the semiconductor module fixed on the first surface of the heat radiating portion and the power component. Therefore, heat interference between the semiconductor module fixed to the outer side of the heat radiating portion and the power component can be reduced, and thus heat radiation performance can be improved.

### BRIEF DESCRIPTION OF THE DRAWINGS

The above and other objects, features and advantages of the present disclosure will become more apparent from the following detailed description made with reference to the accompanying drawings, in which like parts are designated by like reference numbers and in which:

FIG. 1 is a diagram illustrating a top plan view of an electronic control unit according to a first embodiment of the present disclosure;

FIG. 2 is a diagram illustrating a side view of the electronic control unit when viewed along an arrow II in FIG. 1;

FIG. 3 is a circuit diagram of the electronic control unit according to the first embodiment of the present disclosure;

FIG. 4 is a diagram schematically illustrating an electric power steering system to which the electronic control unit according to the first embodiment of the present disclosure is employed;

FIG. 5 is a diagram illustrating a top plan view of an electronic control unit according to a second embodiment of the present disclosure;

FIG. 6 is a diagram illustrating a side view of the electronic control unit when viewed along an arrow VI in FIG. 5;

FIG. 7 is a diagram illustrating a top plan view of an electronic control unit according to a third embodiment of the present disclosure;

FIG. 8 is a diagram illustrating a side view of the electronic control unit when viewed along an arrow VII in FIG. 7;

FIG. 9 is a diagram illustrating a top plan view of an electronic control unit according to a fourth embodiment of the present disclosure;

FIG. 10 is a diagram illustrating a top plan view of an electronic control unit according to a fifth embodiment of the present disclosure;

FIG. 11 is a diagram illustrating a side view of the electronic control unit when viewed along an arrow XI in FIG. 10;

FIG. 12 is a diagram illustrating a top plan view of an electronic control unit according to a sixth embodiment of the present disclosure;

FIG. 13 is a diagram illustrating a top plan view of an electronic control unit according to a seventh embodiment of the present disclosure;

FIG. 14 is a diagram illustrating a side view of the electronic control unit when viewed along an arrow XIV in FIG. 13;

FIG. 15 is a diagram illustrating a top plan view of an electronic control unit according to an eighth embodiment of the present disclosure;

FIG. 16 is a diagram illustrating a top plan view of an electronic control unit according to a ninth embodiment of the present disclosure;

FIG. 17 is a diagram illustrating a side view of the electronic control unit when viewed along an arrow XVII in FIG. 16;

FIG. 18 is a diagram illustrating a top plan view of an electronic control unit according to a tenth embodiment of the present disclosure;

FIG. 19 is a diagram illustrating a top plan view of an electronic control unit according to an eleventh embodiment of the present disclosure;

FIG. 20 is a diagram illustrating a side view of the electronic control unit when viewed along an arrow XX in FIG. 19;

FIG. 21 is a diagram illustrating a top plan view of an electronic control unit according to a twelfth embodiment of the present disclosure;

FIG. 22 is a diagram illustrating a side view of the electronic control unit when viewed along an arrow XXII in FIG. 21;

FIG. 23 is a diagram illustrating a top plan view of an electronic control unit according to a thirteenth embodiment of the present disclosure; and

FIG. 24 is a diagram illustrating a side view of the electronic control unit when viewed along an arrow XXIV in FIG. 23.

### DETAILED DESCRIPTION

Hereinafter, exemplary embodiments of an electronic control unit of the present disclosure will be described with reference to the drawings. In the embodiments described hereinafter, substantially the same parts will be designated with the same reference numbers, and descriptions thereof will not be repeated.

### First Embodiment

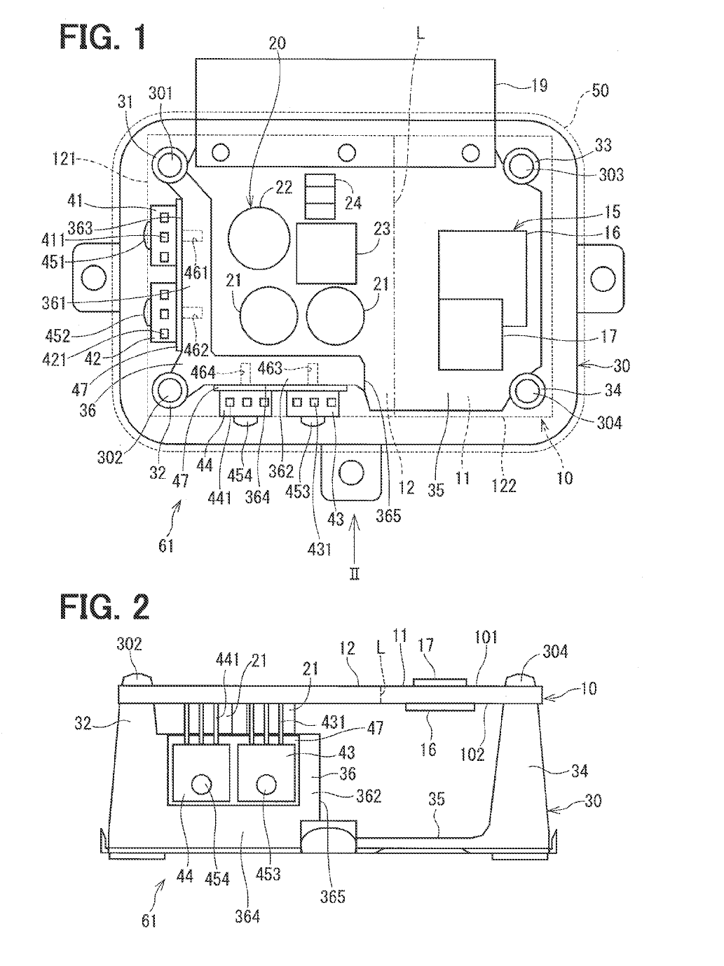

An electronic control unit according to a first embodiment of the present disclosure is shown in FIG. 1 to FIG. 3. An electronic control unit 61 is, for example, employed to a vehicular electric power steering system 100 shown in FIG. 4. The electronic control unit 61 drives and controls a motor 2 that generates an assisting torque for assisting a user's steering operation based on signals, such as a steering torque signal and a vehicle speed signal. The motor 2 is driven by an electric power supplied from a battery 3 via the electronic control unit 61.

As shown in FIG. 1 and FIG. 2, the electronic control unit 61 includes a substrate 10, a control component 15, a power component 20, a housing 30, semiconductor modules 41 to 44, a cover member 50 and the like. FIG. 1 and FIG. 2 are schematic diagrams. In the figures, illustration of the substrate 10 and the cover member 50 are suitably omitted, or the substrate 10 and the cover member 50 are illustrated with dashed lines for a purpose of suitably showing arrangements of other components and the like. Furthermore, in FIG. 2, a connector 19 is not illustrated. These are similar in the drawings of the other embodiments.

The substrate 10 is a printed circuit board, such as FR-4 (Flame Retardant Type 4), made of a glass fiber and an epoxy resin. The substrate 10 has a control region 11 and a power region 12. In the present embodiment, the control region 11 is provided by both surfaces of a right part of the substrate 10 from a single dashed chain line L in FIG. 1, and the power region 12 is provided by both surfaces of a left part of the substrate 10 from the single dashed chain line L in FIG. 1. In the present embodiment, a ground line is disposed at a position of the single dashed chain line L, and thus the control region 11 and the power region 12 are separated from each other on the substrate 10. Alternatively, the control region 11 and the power region 12 may be divided by an imaginary line, without arranging the ground line.

The control component 15, which generates a relatively small amount of heat, is mounted on the control region 11. The power component 20, which generates a relatively large amount of heat, that is, generates heat more than the control component 15, is mounted on the power region 12. The semiconductor modules 41 to 44 are connected to the power region 12. The substrate 10 of the present embodiment is separated into the control region 11 and the power region 12. Therefore, the control component 15 is spatially spaced from the power component 20 and the semiconductor modules 41 to 44. Accordingly, it is less likely that the heat generated from the power component 20 and the semiconductor modules 41 to 44 will be transferred to the control component 15.

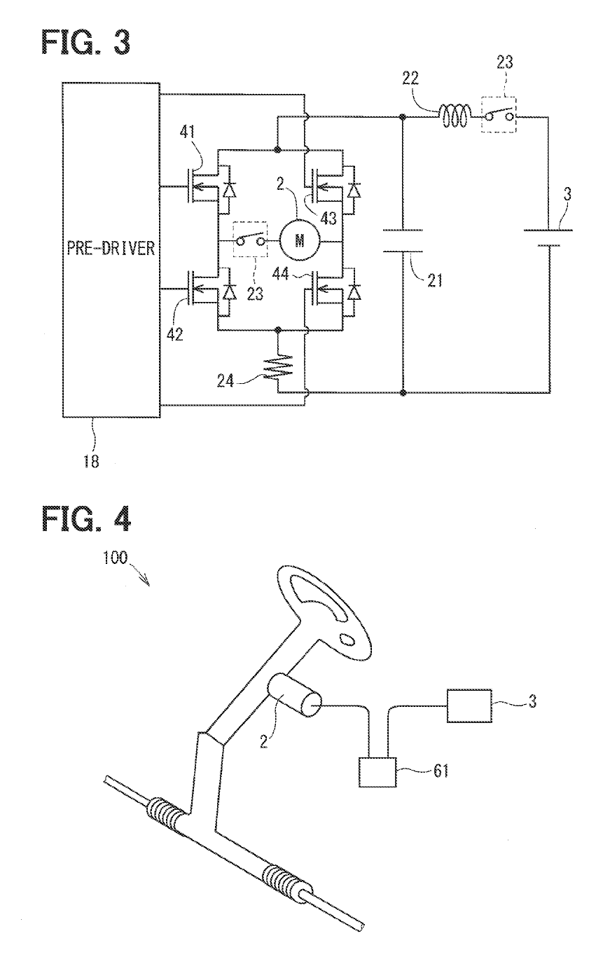

The control component 15 includes an IC 16 and a CPU 17. The IC 16 and the CPU 17 detect a direction of rotation of the motor 2 and a rotation torque of the motor 2. The IC 16 and the CPU 17 controls a pre-driver 18 (see FIG. 3) to output a drive signal, which is based on the steering torque signal and the vehicle speed signal inputted through the connector 19, thereby to control switching of a relay 23 and the semiconductor modules 41 to 44.

In the present embodiment, the IC 16 is disposed on a lower surface 102 of the substrate 10, in the control region 11. The CPU 17 is disposed on an upper surface 101 of the substrate 10, in the control region 11.

The power component 20 includes an aluminum electrolytic capacitor 21, a coil 22, the relay 23, and a shunt resistor 24. The aluminum electrolytic capacitor 21, the coil 22, the relay 23 and the shunt resistor 24 are disposed on the lower surface 102 of the substrate 10, in the power region 12.

The aluminum electrolytic capacitor 21 accumulates electric charges to assist electric power supply to the semiconductor modules 41 to 44, and reduces a noise component such as a surge voltage.

The coil 22 is disposed to reduce noise. The relay 23 is a power source relay or a motor relay, and is disposed for a failsafe. The shunt resistor 24 is disposed so as to detect an electric current provided to the motor 2.

The housing 30 has a first substrate-fixing portion 31, a second substrate-fixing portion 32, a third substrate-fixing portion 33, a fourth substrate-fixing portion 34, a bottom portion 35, a heat radiating portion 36, and the like. The housing 30 is made of a metal or the like having high heat conductivity. In the present embodiment, the first substrate-fixing portion 31, the second substrate-fixing portion 32, the third substrate-fixing portion 33 and the fourth substrate-fixing portion 34 correspond to a “substrate-fixing portion”, and will also be hereinafter referred to as the substrate-fixing portions 31 to 34.

The substrate-fixing portions 31 to 34 project from the bottom portion 35 that is opposed to the substrate 10. The substrate 10 is mounted on the substrate-fixing portions 31 to 34, and is fixed to the substrate-fixing portions 31 to 34 by fastening substrate-fixing screws 301 to 304. Therefore, the substrate 10 is fixed to the housing 30.

The first substrate-fixing portion 31 and the second substrate-fixing portion 32 are disposed on a side adjacent to the power region 12 of the substrate 10, and the third substrate-fixing portion 33 and the fourth substrate-fixing portion 34 are disposed on a side adjacent to the control region 11 of the substrate 10. Also, the first substrate-fixing portion 31 and the third substrate-fixing portion 33 are disposed on a side adjacent to the connector 19, and the second substrate-fixing portion 32 and the fourth substrate-fixing portion 34 are disposed on a side opposite to the connector 19.

The heat radiating portion 36 is continuous to and integral with the first substrate-fixing portion 31 and the second substrate-fixing portion 32, to which the power region 12 of the substrate 10 is fixed. The heat radiating portion 36 extends from the bottom portion 35. In the present embodiment, the heat radiating portion 36 is disposed at a position outside from the area where the power component 20 is mounted. That is, the heat radiating portion 36 is located outside than the power component 20.

The heat radiating portion 36 includes a first heat radiating portion 361 and a second heat radiating portion 362. The first heat radiating portion 361 extends between the first substrate-fixing portion 31 and the second substrate-fixing portion 32. The second heat radiating portion 362 extends from the second substrate-fixing portion 32 toward the fourth substrate-fixing portion 34. Therefore, the heat radiating portion 36 has a substantially L-shape as a whole. In other words, it can be understood that the first substrate-fixing portion 31 is disposed at an end of the heat radiating portion 36, and the second substrate-fixing portion 32 is disposed at the corner of the heat radiating portion 36.

The first heat radiating portion 361 is disposed substantially parallel to a side 121 of the substrate 10 adjacent to the power region 12. The second heat radiating portion 362 is disposed substantially parallel to a side 122 of the substrate 10 opposite to the connector 19, and in a projected area of the connector 19 within the power region 12. That is, the second heat radiating portion 362 toward the fourth substrate-fixing portion 304, and has an end 365 within the power region 12. The second heat radiating portion 362 is disposed such that the end 365 adjacent to the fourth substrate-fixing portion 34 is closer to the control region 11 than an end of the power component 20 adjacent to the control region 11 (e.g., the end of the aluminum electrolytic capacitor 21 adjacent to the control region 11).

The first heat radiating portion 361 and the second heat radiating portion 362 of the present embodiment are recessed inside from the first substrate-fixing portion 31 and the second substrate-fixing portion 32. That is, outer surfaces of the first heat radiating portion 361 and the second heat radiating portion 362 are located more to inside of the housing 30 than the outer ends of the first substrate-fixing portion 31 and the second substrate-fixing portion 32.

The semiconductor modules 41 to 44 are provided by a metal-oxide-semiconductor field-effect transistor (MOSFET), which is a kind of electric field effect transistors. Hereinafter, the semiconductor modules 41 to 44 will also be referred to as “MOSs 41 to 44”.

As shown in FIG. 3, the MOSs 41 to 44 are bridge-connected. The MOSs 41 and 43 are disposed at a high potential side, and the MOSs 42 and 44 are disposed at a low potential side. The MOSs 41 and 43, which are disposed at the high potential side, tend to generate heat more than the MOSs 42 and 44, which are disposed at the low potential side. Hereinafter, the MOSs 41 and 43, which are disposed at the high potential side and provide high potential-side modules, will be also referred to as “upper MOSs 41 and 43”, and the MOSs 42 and 44, which are disposed at the low potential side and provide low potential-side modules, will be also referred to as “lower MOSs 42 and 44”.

In the present embodiment, the driving of the motor 2 is controlled by controlling on and off operations of the MOSs 41 to 44 with the control component 15.

The MOSs 41 and 42 are disposed on a first outer surface 363 of the first heat radiating portion 361, which is on a side opposite to the power component 20. In the present embodiment, fixing holes 461, 462 are formed on the first outer surface 363 of the first heat radiating portion 361. The MOSs 41 and 42 are fixed to the first outer surface 363 of the first heat radiating portion 361 through a heat-radiating and insulating sheet 47 by fastening MOS-fixing screws 451, 452 into the fixing holes 461, 462.

The MOSs 43 and 44 are disposed on a second outer surface 364 of the second heat radiating portion 362, which is on a side opposite to the power component 20. In the present embodiment, fixing holes 463, 464 are formed on the second outer surface 364 of the second heat radiating portion 362. The MOSs 43 and 44 are fixed to the second outer surface 364 of the second heat radiating portion 362 through a heat-radiating and insulating sheet 47 by fastening MOS-fixing screws 453, 454 into the fixing holes 463, 464.

In the present embodiment, the first outer surface 363 and the second outer surface 364 may correspond to the “first surface” of the heat radiating portion and the “surface on which the semiconductor module is disposed. For example, the first outer surface 363 and the second outer surface 364 may correspond to the “perpendicular surface perpendicular to the bottom portion 35 and on which the semiconductor module is disposed”. In the figures, the fixing holes 461 to 464 are illustrated with dashed lines. In regard to the MOS-fixing screws 451 to 454, only head portions thereof are illustrated and shaft portions thereof are not illustrated.

In the present embodiment, the first outer surface 363 and the second outer surface 364 on which the MOSs 41 to 44 are perpendicular to the bottom portion 35.

The MOSs 41 to 44 are fixed to the heat radiating portion 36 such that leads 411, 421, 431, 441 are located on a side adjacent to the substrate 10. The MOSs 41 to 44 are electrically connected to the power region 12 of the substrate 10 through the leads 411, 421, 431, 441. In the present embodiment, since the first heat radiating portion 361 and the second heat radiating portion 362 are recessed inside, the MOSs 41 to 44 are located within a projected area of the substrate 10. Therefore, when the MOSs 41 to 44 are connected to the substrate 10, it is not necessary to bend the leads 411, 421, 431, 441. As such, the length of the leads 411, 421, 431, 441 can be reduced.

In the present embodiment, among the MOSs 41 to 44, the upper MOS 41, which generates a relatively large amount of heat, is disposed adjacent to the first substrate-fixing portion 31 on the first heat radiating portion 361, and the upper MOS 43, which generates a relatively large amount of heat, is disposed adjacent to the end 365 on the second heat radiating portion 362. The lower MOS 42, which generates a relatively small amount of heat, is disposed adjacent to the second substrate-fixing portion 32 on the first heat radiating portion 361. The lower MOS 44, which generates a relatively small amount of heat, is disposed adjacent to the second substrate-fixing portion 32 on the second heat radiating portion 362.

Namely, in the present embodiment, the upper MOSs 41, 43, which generate a relatively large amount of heat, are arranged at ends. Since the positions where the heat is generated, that is, the heat generating portions are dispersed, a heat radiation performance improves.

The cover member 50 is engaged with the bottom portion 35 of the housing 30 in a state where the substrate 10, the control component 15, the power component 20, the substrate fixing portions 31 to 34, the heat radiating portion 36 and the MOSs 41 to 44 are accommodated in the cover member 50, that is, in a space provided between the cover member 50 and the housing 30, and the connector 19 exposes from the cover member 50.

In the present embodiment, the first heat radiating portion 361 and the second heat radiating portion 362 are recessed inside, and the MOSs 41 to 44 are located within the projected area of the substrate 10. Therefore, it is less likely that the MOSs 41 to 44 will contact with the cover member 50.

As described above in detail, the electronic control unit 61 of the present embodiment includes the substrate 10, the control component 15, the power component 20, the housing 30 and the MOSs 41 to 44. The substrate 10 has the control region 11 and the power region 12. The control component 15 is disposed in the control region 11 of the substrate 10. The power component 20 is disposed in the power region 12 of the substrate 10.

The housing 30 has the bottom portion 35 opposed to the substrate 10, the substrate-fixing portions 31 to 34, and the heat radiating portion 36. The substrate fixing portions 31 to 34 project from the bottom portion 35, and the substrate 10 is fixed to the substrate fixing portions 31 to 34. The heat radiating portion 36 extends from the bottom portion 35.

The MOSs 41 to 44 are disposed along the heat radiating portion 36, and is connected to the power region 12 of the substrate 10.

The MOSs 41 to 44 are disposed on the first outer surface 363 and the second outer surface 364 of the heat radiating portion 36, which are on a side opposite to the side adjacent to the power component 20.

(1) In the present embodiment, the power component 20 and the MOSs 41 to 44, which generate a relatively large amount of heat, are located in the power region 12 of the substrate 10, and the control component 15, which generates a relatively small amount of heat, is located in the control region 11 of the substrate 10. In this structure, since the control component 15 is spatially spaced from the power component 20 and the MOSs 41 to 44, heat generated from the power component 20 and the MOSs 41 to 44 are not easily transferred to the control component 15. Therefore, it is not necessary to use a high temperature-guaranteed component for the control component 15. Accordingly, the costs can be reduced.

The MOSs 41 to 44 are fixed to the outer surfaces 363, 364 of the heat radiating portion 36. That is, the heat radiating portion 36 is located between the MOSs 41 to 44 and the power component 20. Therefore, heat interference between the MOSs 41 to 44 and the power component 20 can be reduced, and thus a heat radiation performance improves.

(2) The heat radiating portion 36 is integral with the first substrate-fixing portion 31 and the second substrate-fixing portion 32 to which the power region 12 of the substrate 10 is fixed. Therefore, the heat generated from the MOSs 41 to 44 can be transferred to the substrate 10 via the heat radiating portion 36 and the substrate fixing portions 31, 32, and radiated also from the substrate 10. As such, the heat radiation performance improves.

(3) The first outer surface 363 and the second outer surface 364 of the heat radiating portion 36 on which the MOSs 41 to 44 are disposed are perpendicular to the bottom portion 35. Therefore, the size of the electronic control unit 61 can be reduced in a width direction (left and right direction in FIG. 1) and in a depth direction (up and down direction in FIG. 1).

(4) The upper MOSs 41 and 43, which are on the high potential side, are fixed to the outer surface 363, 364 of the heat radiating portion 36. The heat radiating portion 36 is located between the power component 20 and the upper MOSs 41 and 43, which generate a relatively large amount of heat. Therefore, the upper MOSs 41 and 43 will not be easily affected by the heat generated from the power component 20, and thus the heat interference can be reduced.

(5) In the present embodiment, particularly, all the MOSs 41 to 44 are fixed to the outer surfaces 363, 364 of the heat radiating portion 36. Therefore, since the heat radiating portion 36 is located between all the MOSs 41 to 44 and the power component 20, the heat interference between the MOSs 41 to 44 and the power component 20 can be further reduced.

(6) The heat radiating portion 36 is disposed to extend along two sides 121, 122 of the substrate 10. Therefore, the outer surfaces 363, 364 of the heat radiating portion 36 can provide wide areas for fixing the semiconductor modules.

(7) The first substrate-fixing portion 31 and the second substrate-fixing portion 32, which are integral with the heat radiating portion 36, are disposed at the end and the corner of the heat radiating portion 36. In the present embodiment, the first substrate-fixing portion 31 is fixed to the end of the heat radiating portion 36, and the second substrate-fixing portion 32 is formed at the corner of the heat radiating portion 36. Therefore, the thickness of the heat radiating portion 36 can be reduced irrespective to the size of the substrate-fixing portions 31, 32. Further, the area to which the MOSs 41 to 44 can be fixed is widely ensured.

### Second Embodiment

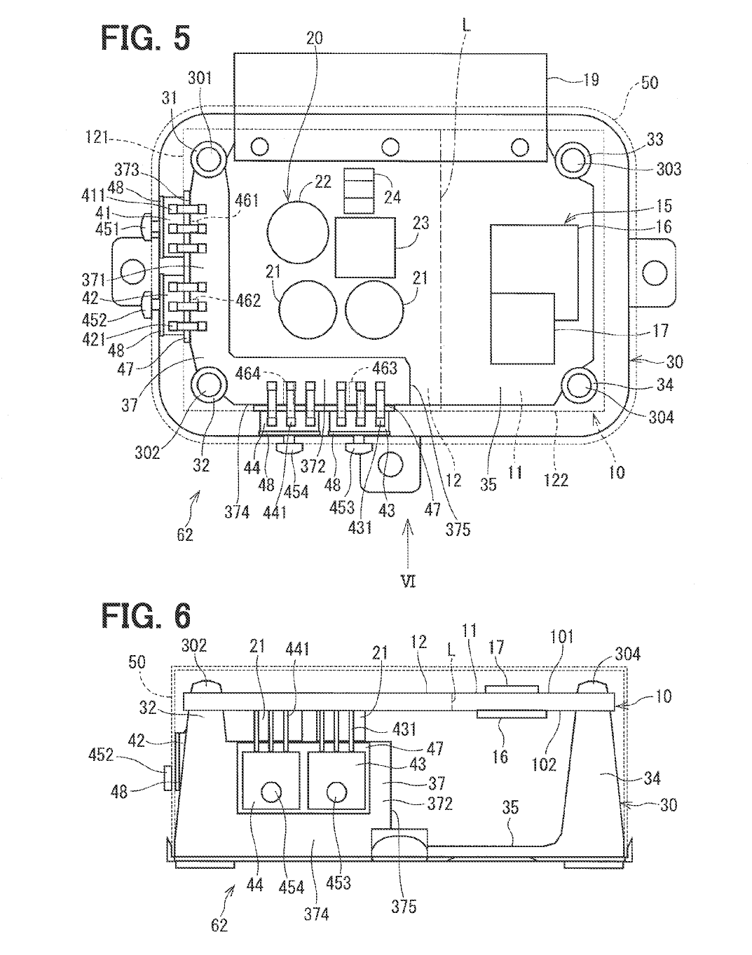

An electronic control unit according to a second embodiment of the present disclosure will be described with reference to FIGS. 5 and 6.

An electronic control unit 62 of the second embodiment has a heat radiating portion 37. The heat radiating portion 37 includes a first heat radiating portion 371 and a second heat radiating portion 372. The first heat radiating portion 371 is disposed between the first substrate-fixing portion 31 and the second substrate-fixing portion 32. The second heat radiating portion 372 extends from the second substrate-fixing portion 32 toward the fourth substrate-fixing portion 34.

The first heat radiating portion 371 is disposed substantially parallel to the side 121 of the substrate 10 adjacent to the power region 12, similar to the embodiment described above. The second heat radiating portion 372 is disposed substantially parallel to the side 122 of the substrate 10, which is opposite to the connector 19, within the power region 12, similar to the embodiment described above. Further, the end 375 of the second heat radiating portion 372 adjacent to the fourth substrate-fixing portion 34 is located closer to the control region 11 than an end of the power component 20 adjacent to the control region 11.

The MOSs 41 and 42 are fixed to a first outer surface 373 of the first heat radiating portion 371, which is on a side opposite to the power component 20, with MOS-fixing screws 451, 452. A heat-radiating and insulating sheet 47 is disposed between the MOSs 41 and 42 and the first heat radiating portion 371. That is, the MOSs 41 and 42 are fixed to the first heat radiating portion 371 in a state where the heat-radiating and insulating sheet 47 is interposed between the MOSs 41 and 42 and the first heat radiating portion 371.

The MOSs 43 and 44 are fixed to a second outer surface 374 of the second heat radiating portion 372, which is on a side opposite to the power component 20, with MOS-fixing screws 453, 454. A heat-radiating and insulating sheet 47 is disposed between the MOSs 43 and 44 and the second heat radiating portion 372. That is, the MOSs 43 and 44 are fixed to the second heat radiating portion 372 in a state where the heat-radiating and insulating sheet 47 is interposed between the MOSs 43 and 44 and the second heat radiating portion 372.

In the present embodiment, the first outer surface 373 and the second outer surface 374 may correspond to the “first surface” of the heat radiating portion and the “surface on which the semiconductor module is disposed”. For example, the first outer surface 373 and the second outer surface 374 may correspond to the “perpendicular surface perpendicular to the bottom portion 35 and on which the semiconductor module is disposed”.

In the present embodiment, the surfaces of the MOSs 41 to 44 opposite to the heat radiating portion 37 are fastened together with the cover member 50 through heat-radiating and insulating sheets 48. Therefore, the heat generated from the MOSs 41 to 44 is dissipated to the cover member 50, in addition to the heat radiating portion 37. Therefore, the heat radiation performance of the MOSs 41 to 44 improves.

That is, the heat radiating portion 37 of the present embodiment is formed to protrude outside so that the MOSs 41 to 44 are fastened together with the cover member 50. The heat radiating portion 37 has a shape that enables the MOSs 41 to 44 to be fastened together with the cover member 50, according to shapes of the MOSs 41 to 44 and the cover member 50 and the like.

(8) In the present embodiment, the electronic control unit 62 includes the cover member 50 that can accommodate the substrate 10, the control component 15, the power component 20, the heat radiating portion 37, and the MOSs 41 to 44 therein. The MOSs 41 to 44 are disposed outside of the heat radiating portion 37, and are fixed in the state of being interposed between the heat radiating portion 37 and the cover member 50. Therefore, the heat generated from the MOSs 41 to 44 can be radiated not only to the heat radiating portion 37 but also to the cover member 50 disposed on the back side. Namely, the MOSs 41 to 44 also has a back side heat radiation structure. Therefore, the het radiation performance of the MOSs 41 to 44 further improves.

In addition, the similar effects to the embodiment described above, in particular, the effects (1) to (7) are also achieved.

### Third Embodiment

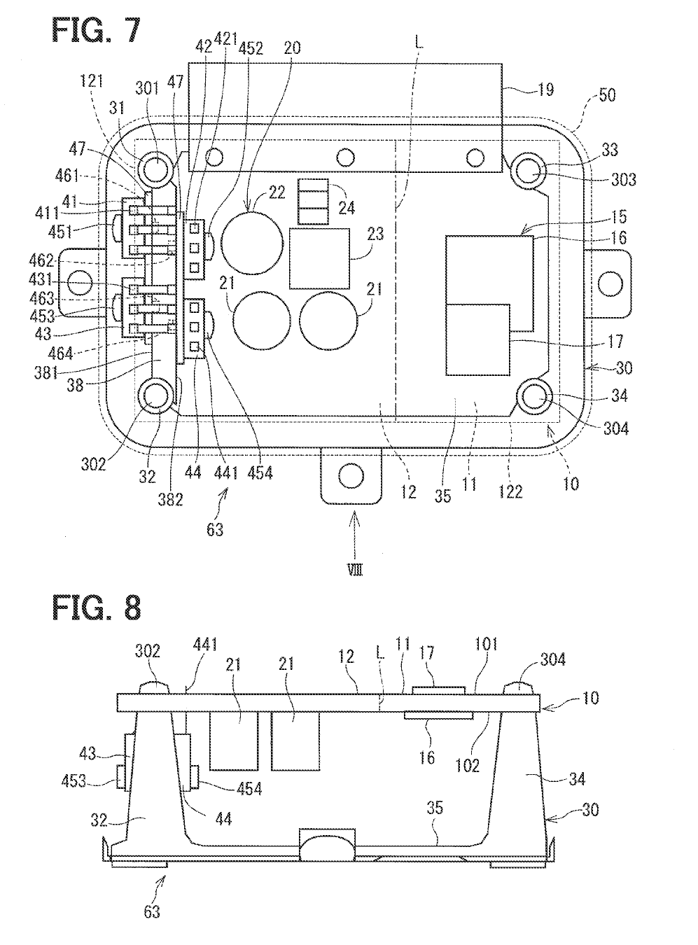

An electronic control unit according to a third embodiment of the present disclosure is shown in FIGS. 7 and 8.

An electronic control unit 63 of the present embodiment has a heat radiating portion 38. The heat radiating portion 38 is disposed between the first substrate-fixing portion 31 and the second substrate-fixing portion 32, and is substantially parallel to the side 121 of the substrate 10 adjacent to the power region 12. In this case, the heat radiating portion 38 does not have a portion corresponding to the second heat radiating portion of the embodiments described above. The heat radiating portion 38 has a straight shape, in place of the L-shape. Therefore, the volume of the housing can be reduced, as compared with the embodiments described above.

In the present embodiment, fixing holes 461, 463 for fixing the upper MOSs 41 and 43 are formed on an outer surface 381 of the heat radiating portion 38. Also, fixing holes 462, 464 for fixing the lower MOSs 42 and 44 are formed on an inner surface 382 of the heat radiating portion 38.

In the present embodiment, the upper MOSs 41 and 43, which generate a relatively large amount of heat, are fixed to the outer surface 381 of the heat radiating portion 38 through the heat-radiating and insulating sheet 47, and the lower MOSs 42, 44 are fixed to the inner surface 382 of the heat radiating portion 38 through the heat-radiating and insulating sheet 47. Therefore, since the heat radiating portion 38 is located between the upper MOSs 41 and 43, which generate a relatively large amount of heat, and the power component 20, such as the aluminum electrolytic capacitor 21, it is less likely that the upper MOSs 41 and 43 will be affected by the heat generated from the power component 20 and the lower MOSs 42 and 44. As such, the heat interference is reduced.

In the present embodiment, the outer surface 381 and the inner surface 382 may correspond to the “surface on which the semiconductor module is disposed”. For example, the outer surface 381 and the inner surface 382 may correspond to the “perpendicular surface perpendicular to the bottom portion 35 and on which the semiconductor module is disposed”. The outer surface 381 may also correspond to a “first surface”, and the inner surface 382 may also corresponds to a “second surface”. Further, the MOSs 41 and 43 may correspond to a “first module”, and the MOSs 42 and 44 may correspond to a “second module”.

In the present embodiment, the upper MOS 41 and the lower MOS 42 are offset from each other in a lateral direction (up and down direction in FIG. 7) relative to an opposed position. Likewise, the upper MOS 43 and the lower MOS 44 are offset from each other relative to an opposed position in the lateral direction. Namely, the upper MOS 41 and the lower MOS 42 are disposed at offset positions from each other on the opposite sides of the heat radiating portion 38. Likewise, the upper MOS 43 and the lower MOS 44 are disposed at offset positions from each other on the opposite sides of the heat radiating portion 38. For example, the upper MOS 41 and the lower MOS 42 are offset from each other in a longitudinal direction of the heat radiating portion 38, and the upper MOS 43 and the lower MOS 44 are offset from each other in the longitudinal direction of the heat radiating portion 38.

(9) In the present embodiment, the heat radiating portion 38 is disposed along the side 121 of the substrate 10. Also, the MOSs 41 and 43 are fixed to the outer surface 381 of the heat radiating portion 38, and the MOSs 42, 44 are fixed to the inner surface 382 of the heat radiating portion 38.

Therefore, the volume of the housing 30 can be reduced, as compared with a case where the heat radiating portions are disposed along two sides of the substrate 10, and thus the weight of the electronic control unit 63 can be reduced.

(10) The MOSs 41 and 43 are respectively offset from the MOSs 42 and 44 in the longitudinal direction of the heat radiating portion 38. Therefore, the heat generating positions are dispersed, and thus the heat radiation performance improves. In addition, the fixing holes 461 to 464 for fixing the MOSs 41 to 44 can be formed at offset positions. Therefore, the thickness of the heat radiating portion 38 can be reduced. As such, the volume of the housing 30 can be reduced, and thus the weight can be reduced.

Further, the similar effects to the embodiments described above, in particular, the similar effects to (1) to (4) and (7) are achieved.

A fourth embodiment to a sixth embodiment are modifications of the third embodiment. In the fourth embodiment to the sixth embodiment, similar to the third embodiment, the upper MOSs 41 and 43 are fixed to the outer surface 381 of the heat radiating portion 38, and the lower MOSs 42 and 44 are fixed to the inner surface 382 of the heat radiating portion 38.

### Fourth Embodiment

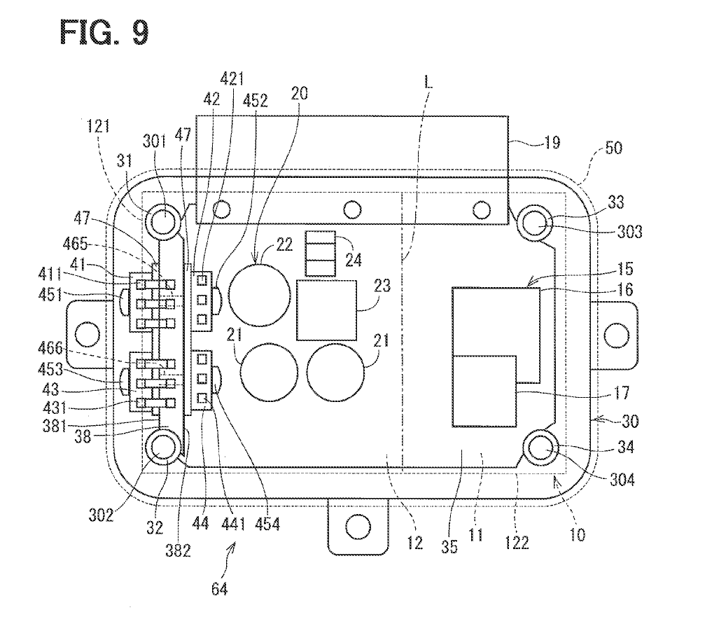

An electronic control unit according to the fourth embodiment of the present disclosure is shown in FIG. 9. It is to be noted that the side view of the electronic control unit of the fourth embodiment is substantially the same as that of the third embodiment.

In an electronic control unit 64 of the present embodiment, the MOS 41 is disposed at a position opposite to the MOS 42 through the heat radiating portion 38. The MOS 41 and the MOS 42 are fastened to the heat radiating portion 38 from opposite ends of a common through hole 465 with the MOS-fixing screws 451, 452. Likewise, the MOS 43 is disposed at a position opposite to the MOS 44 through the heat radiating portion 38. The MOS 43 and the MOS 44 are fastened to the heat radiating portion 38 from opposite ends of a common through hole 466 with the MOS-fixing screws 453, 454.

(11) In the present embodiment, the MOS 41 and the MOS 42 are disposed at the positions opposite to each other through the heat radiating portion 38. Further, the MOS 41 and the MOS 42, which are disposed at the positions opposite to each other through the heat radiating portion 38, are fixed at the opposite ends of the through hole 465 formed in the heat radiating portion 38. Also, the MOS 43 and the MOS 44, which are disposed at the positions opposite to each other through the heat radiating portion 38 are fixed at the opposite ends of the through hole 466 formed in the heat radiating portion 38. Therefore, the umber of steps of processing the holes for fixing the MOSs 41 to 44 can be reduced.

Further, the similar effects to the embodiments described above, in particular, the effects similar to (1) to (4), (7), and (9) are achieved.

### Fifth Embodiment

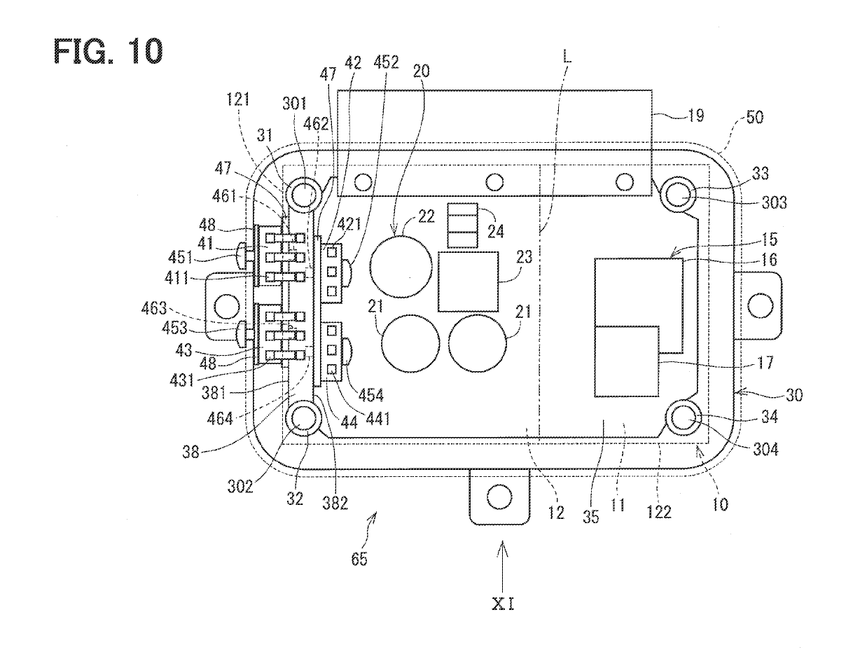

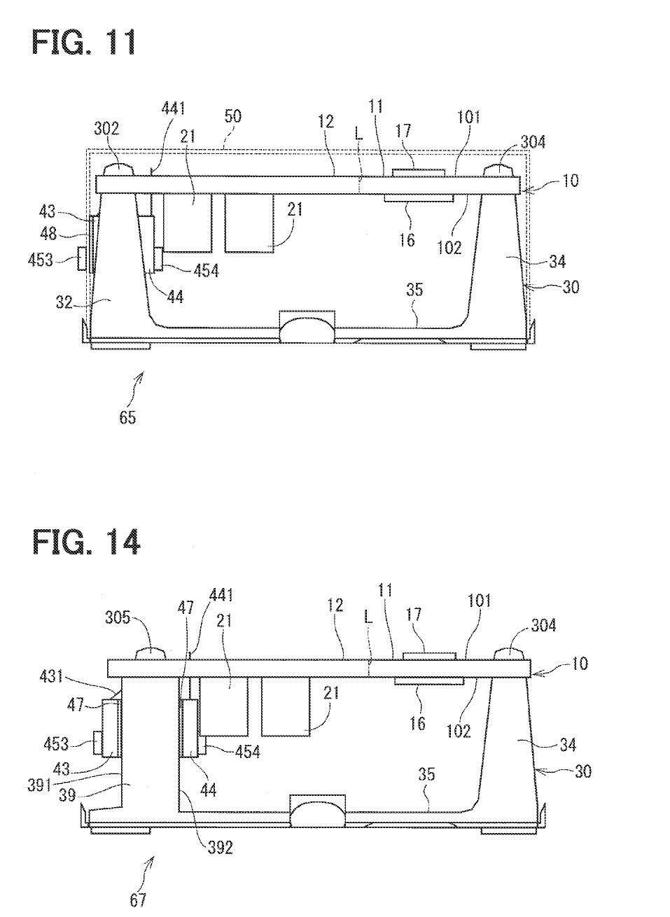

An electronic control unit according to a fifth embodiment of the present disclosure is shown in FIG. 10 and FIG. 11.

In an electronic control unit 65 according to the present embodiment, similar to the third embodiment, the upper MOS 41 and the lower MOS 42 are offset from each other in the lateral direction (up and down direction in FIG. 10) relative to the opposed position. Likewise, the upper MOS 43 and the lower MOS 44 are offset from each other in the lateral direction relative to the opposed position.

In the present embodiment, the upper MOSs 41 and 43, which are fixed to the outer surface 381 of the heat radiating portion 38, are fastened together with the cover member 50 through the heat-radiating and insulating sheet 48. That is, in the present embodiment, the upper MOSs 41, 43 can radiate heat not only to the heat radiating portion 38 but also to the cover member 50 disposed on the back side. Therefore, it can be said that the upper MOSs 41, 43 also have the back side heat radiation structure. As such, the heat radiation performance of the upper MOSs 41 and 43 fixed to the outer surface 381 improves.

Therefore, the similar effects to the embodiments described above, in particular, the effects similar to (1) to (4), and (7) to (10) are achieved.

### Sixth Embodiment

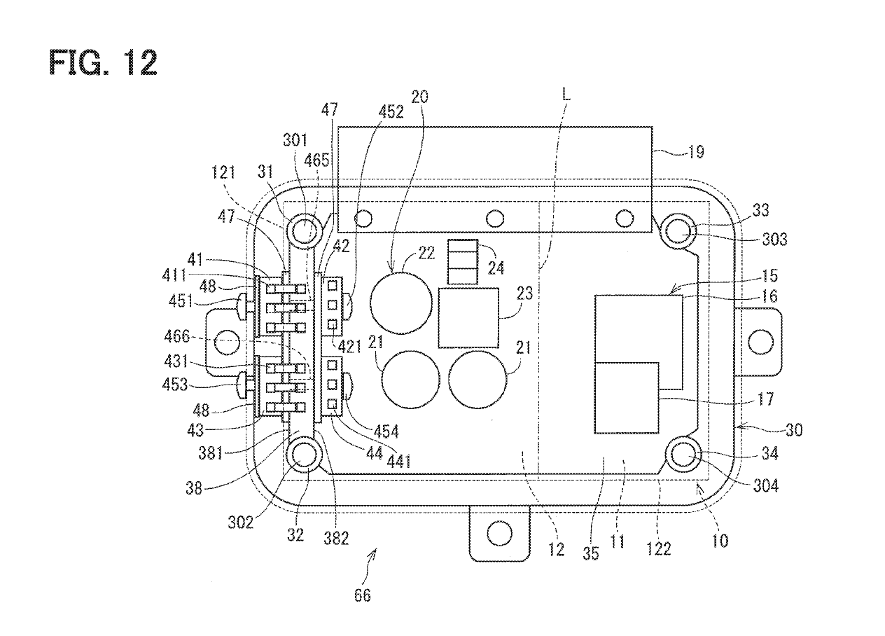

An electronic control unit according to a sixth embodiment of the present disclosure is shown in FIG. 12. It is to be noted that the side view of the electronic control unit of the present embodiment is substantially the same as that of the fifth embodiment.

In an electronic control unit 66 according to the present embodiment, similar to the fourth embodiment, the MOS 41 is disposed at a position opposite to the MOS 42 through the heat radiating portion 38. The MOS 41 and the MOS 42 are fastened to the heat radiating portion 38 from opposite ends of the common through hole 465 with the MOS-fixing screws 451, 452. Likewise, the MOS 43 is disposed at a position opposite to the MOS 44 through the heat radiating portion 38. The MOS 43 and the MOS 44 are fastened to the heat radiating portion 38 from opposite ends of the common through hole 466 with the MOS-fixing screws 453, 454.

Further, similar to the fifth embodiment, the upper MOSs 41 and 43, which are fixed to the outer surface 381 of the heat radiating portion 38, are fastened together with the cover member 50 through the heat-radiating and insulating sheet 48. That is, in the present embodiment, the upper MOSs 41, 43 can radiate heat not only to the heat radiating portion 38 but also to the cover member 50 disposed on the back side. Therefore, it can be said that the upper MOSs 41, 43 also have the back side heat radiation structure. As such, the heat radiation performance of the upper MOSs 41 and 43 fixed to the outer surface 381 improves.

Therefore, the similar effects to the embodiments described above, in particular, the effects similar to (1) to (4), (7) to (9) and (11) are achieved.

### Seventh Embodiment

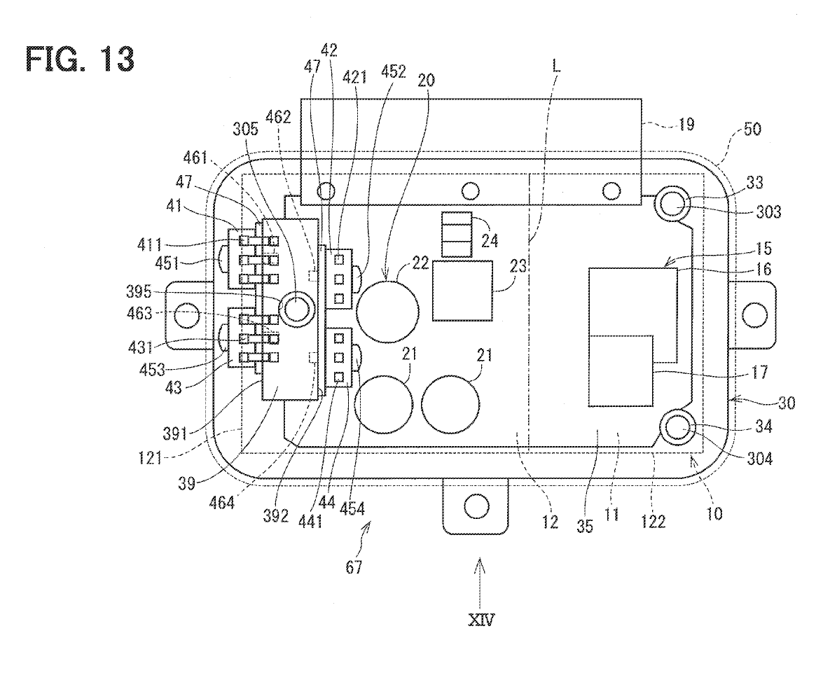

An electronic control unit according to a seventh embodiment of the present disclosure is shown in FIG. 13 and FIG. 14.

In an electronic control unit 67 of the present embodiment, a heat-radiating and fixing portion 39 serves as the “substrate-fixing portion” as well as the “heat radiating portion”.

The heat-radiating and fixing portion 39 is disposed substantially parallel to the side 121 of the substrate 10 adjacent to the power region 12, at a position in between the side 121 of the substrate 10 and the area where the power component 20 is disposed. In the present embodiment, a fifth substrate-fixing portion 395 is formed at a substantially middle of the heat-radiating and fixing portion 39. The power region 12 of the substrate 10 is fixed to the fifth substrate-fixing portion 395 with a substrate-fixing screw 305.

Namely, in the embodiments described above, the power region 12 of the substrate 10 is fixed to the housing 30 at the two positions, that is, at the first substrate-fixing portion 31 and the second substrate-fixing portion 32. In the present embodiment, on the other hand, the power region 12 of the substrate 10 is fixed to the housing 30 at one position, that is, at the fifth substrate-fixing portion 395.

In the present embodiment, the fixing holes 461, 463 for fixing the upper MOSs 41 and 43 are formed on the outer surface 391 of the heat-radiating and fixing portion 39, and the fixing holes 462, 464 for fixing the lower MOSs 42, 44 are formed on the inner surface 392 of the heat-radiating and fixing portion 39. In the present embodiment, the fifth substrate-fixing portion 395 is formed at the substantially middle of the heat-radiating and fixing portion 39. Further, the fixing holes 461, 462 and the fixing holes 463, 464 are formed on opposite sides of the fifth substrate-fixing portion 395.

In the present embodiment, the upper MOSs 41 and 43, which generate a relatively large amount of heat, are fixed to the outer surface 391 of the heat-radiating and fixing portion 39 through the heat-radiating and insulating sheet 47 with the MOS-fixing screws 451, 453. Also, the lower MOSs 42 and 44 are fixed to the inner surface 392 of the heat-radiating and fixing portion 39 through the heat-radiating and insulating sheet 47 with the MOS-fixing screws 452, 454.

Therefore, the heat-radiating and fixing portion 39 is located between the upper MOSs 41 and 43, which generate a relatively large amount of heat, and the power component 20 such as the aluminum electrolytic capacitor 21 and the lower MOSs 42 and 44. As such, it is less likely that the upper MOSs 41 and 43 will be affected by the heat generated from the power component 20 and the lower MOSs 42 and 44, and thus the heat interference can be reduced.

Further, the upper MOS 41 and the lower MOS 42 are offset from each other in the lateral direction (up and down direction in FIG. 13) relative to the opposed position. Likewise, the upper MOS 43 and the lower MOS 44 are offset from each other in the lateral direction relative to the opposed position.

(12) In the present embodiment, the fifth substrate-fixing portion 395 is formed at the middle of the heat-radiating and fixing portion 39. The fifth substrate-fixing portion 395 is formed in the one position, at the middle of the heat-radiating and fixing portion 39. Therefore, the number of the screw for fixing the substrate 10 can be reduced by one, as compared with a case where the substrate 10 is fixed at the opposite sides of the heat radiating portion. Therefore, the number of components can be reduced.

Further, the similar effects to the embodiments described above, in particular, the effects similar to (1) to (4), (9), and (10) are achieved.

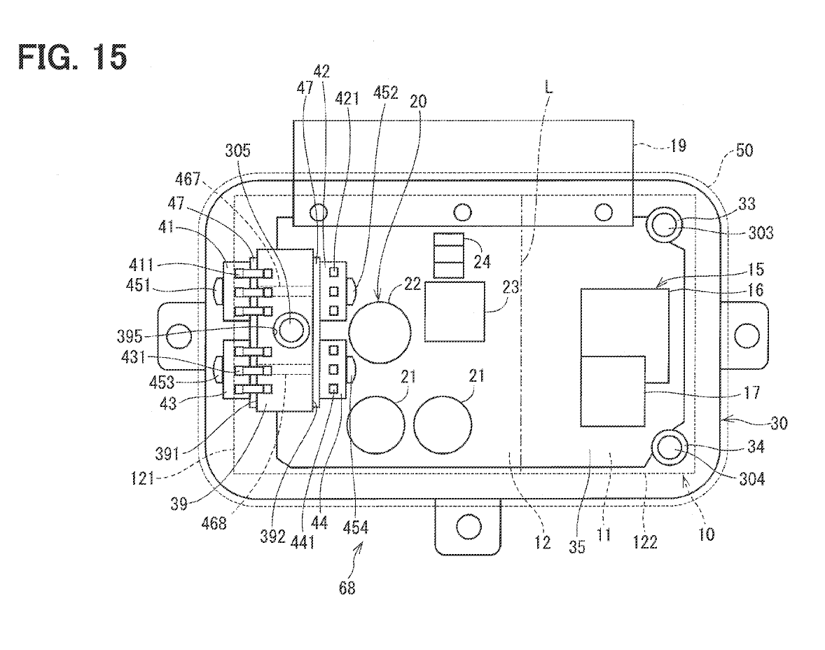

Electronic controls units according to an eighth embodiment to a tenth embodiment of the present disclosure are shown in FIG. 15 to FIG. 18.

The eighth embodiment to the tenth embodiment are modifications of the seventh embodiment. Similar to the seventh embodiment, the heat-radiating and fixing portion 39 serves as the “substrate-fixing portion” as well as the “heat radiating portion”. The upper MOSs 41 and 43 are fixed to the outer surface 391 of the heat-radiating and fixing portion 39, and the lower MOSs 42, 44 are fixed to the inner surface 392 of the heat-radiating and fixing portion 39.

The fifth substrate-fixing portion 395 is formed at the middle of the heat-radiating and fixing portion 39.

### Eighth Embodiment

The electronic control unit according to the eighth embodiment of the present disclosure is shown in FIG. 15. It is to be noted that the side view of the electronic control unit of the eighth embodiment is substantially the same as that of the seventh embodiment.

In an electronic control unit 68 of the present embodiment, the MOS 41 is disposed at a position opposite to the MOS 42 through the heat-radiating and fixing portion 39. The MOS 41 and the MOS 42 are fastened to the heat-radiating and fixing portion 39 from opposite sides of a common through hole 467 with the MOS-fixing screws 451, 452. Further, the MOS 43 and the MOS 44 are fastened to the heat-radiating and fixing portion 39 from opposite sides of a common through hole 468 with the MOS-fixing screws 453, 454.

The through hole 467 and the through hole 468 are disposed on opposite sides of the fifth substrate-fixing portion 395. Therefore, the MOSs 41 and 42 and the MOSs 43 and 44 are disposed on opposite sides of the fifth substrate-fixing portion 395.

As such, the similar effects to the embodiments described above, in particular, the effects similar to (1) to (4), (9), (11) and (12) are achieved.

### Ninth Embodiment

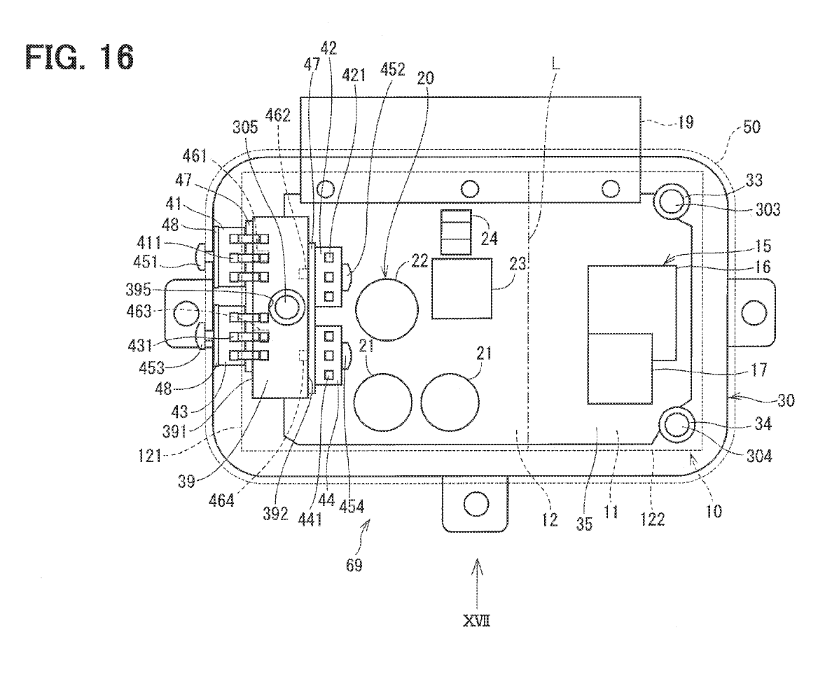

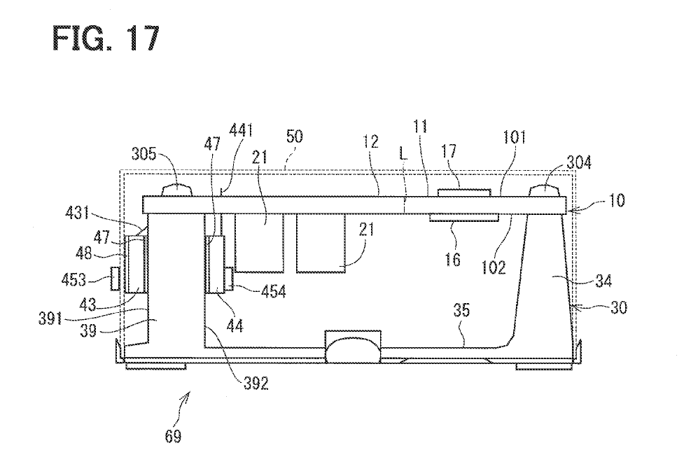

The electronic control unit according to the ninth embodiment of the present disclosure is shown in FIG. 16 and FIG. 17.

In an electronic control unit 69 of the present embodiment, similar to the seventh embodiment, the upper MOS 41 and the lower MOS 42 are offset from each other in the lateral direction (up and down direction in FIG. 16) relative to the opposed position. Likewise, the upper MOS 43 and the lower MOS 44 are offset from each other in the lateral direction relative to the opposed position.

In the present embodiment, the upper MOSs 41 and 43, which are fixed to the outer surface 391 of the heat-radiating and fixing portion 39, are fastened together with the cover member 50 through the heat-radiating and insulating sheet 48. That is, in the present embodiment, the MOSs 41 and 43 can radiate heat not only to the heat-radiating and fixing portion 39 but also to the cover member 50 disposed on the back side. Therefore, it can be said that the upper MOSs 41 and 43 have the back side heat radiation structure. As such, the heat radiation performance of the upper MOSs 41 and 43, which are fixed to the outer surface 391, improves.

Accordingly, the similar effects to the embodiments described above, in particular, the effects similar to (1) to (4), (8), (9), (10) and (11) are achieved.

### Tenth Embodiment

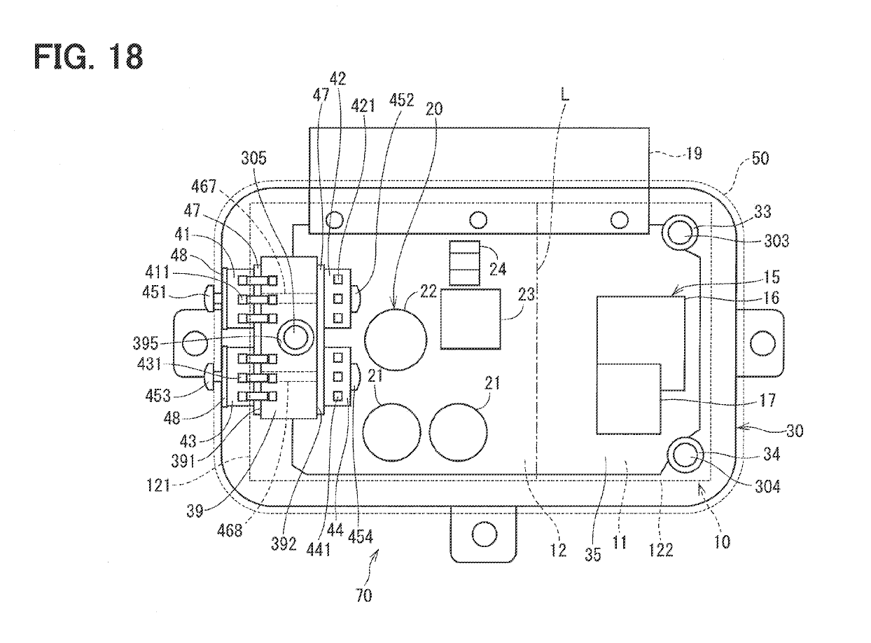

The electronic control unit according to the tenth embodiment of the present disclosure is shown in FIG. 18. It is to be noted that the side view of the electronic control unit of the present embodiment is the same as that of the ninth embodiment.

In an electronic control unit 70 of the present embodiment, the MOS 41 is disposed at a position opposite to the MOS 42 through the heat-radiating and fixing portion 39. The MOS 41 and the MOS 42 are fastened to the heat-radiating and fixing portion 39 from opposite sides of the common through hole 467 with the MOS-fixing screws 451, 452. Further, the MOS 43 and the MOS 44 are fastened to the heat-radiating and fixing portion 39 from opposite sides of the common through hole 468 with the MOS-fixing screws 453, 454.

The through hole 467 and the through hole 468 are disposed on opposite sides of the fifth substrate-fixing portion 395. Therefore, the MOSs 41 and 42 and the MOSs 43 and 44 are disposed on opposite sides of the fifth substrate-fixing portion 395.

Further, similar to the ninth embodiment, the upper MOSs 41 and 43, which are fixed to the outer surface 391 of the heat-radiating and fixing portion 39, are fastened together with the cover member 50 through the heat-radiating and insulating sheet 48. That is, in the present embodiment, the upper MOSs 41 and 43 can radiate heat not only to the heat-radiating and fixing portion 39 but also to the cover member 50 disposed on the back side. Therefore, it can be said that the upper MOSs 41 and 43 have the back side heat radiation structure. As such, the heat radiation performance of the upper MOSs 41 and 43, which are fixed to the outer surface 391, improves.

Further, the similar effects to the embodiments described above, in particular, the effects similar to (1) to (4), (8), (9), (11) and (12) are achieved.

### Eleventh Embodiment

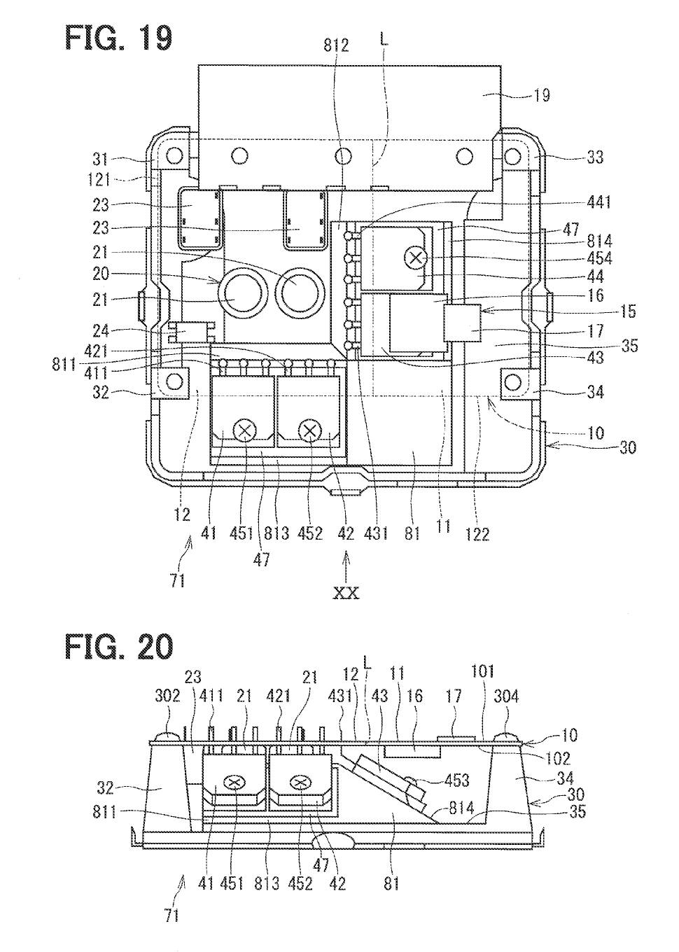

An electronic control unit according to an eleventh embodiment of the present disclosure will be described with reference to FIG. 19 and FIG. 20. In FIG. 19 and subsequent figures, illustration of the cover member 50 and the substrate-fixing screws 301 to 304 are suitably omitted.

An electronic control unit 71 of the present embodiment has a heat radiating portion 81 projecting from the bottom portion 35 toward the substrate 10.

The heat radiating portion 81 includes a first heat radiating portion 811 and a second heat radiating portion 812.

The first heat radiating portion 811 is disposed substantially parallel to the side 122 of the substrate 10 opposite to the connector 19, within the projected area of the power region 12.

The second heat radiating portion 812 extends substantially perpendicular to the first heat radiating portion 811, from the end of the first heat radiating portion 811 adjacent to the fourth substrate-fixing portion 34, toward the connector 19. Further, the second heat radiating portion 812 is disposed at a position closer to the control region 11 than the end of the power component 20 adjacent to the control region 11, within the projected area of the power region 12.

In the present embodiment, a space is provided between the first heat radiating portion 811 and the second substrate-fixing portion 32. The heat radiating portion 81 and the substrate-fixing portions 31 to 34 are formed as separate parts. In this case, the heat radiating portion 81 and the substrate-fixing portions 31 to 34 both project from the bottom portion 35. However, the heat radiating portion 81 and the substrate-fixing portions 31 to 34 are discontinuous to each other. “The heat radiating portion 81 and the substrate-fixing portions 31 to 34 are formed as the separate parts” means that “the heat radiating portion 81 and the substrate-fixing portions 31 to 34 are discontinuous to each other except for the bottom portion 35”.

The first heat radiating portion 811 has a first outer surface 813 on a side opposite to the power component 20. Also, the second heat radiating portion 812 has a second outer surface 814 on a side opposite to the power component 20. In the present embodiment, the first outer surface 813 and the second outer surface 814 are inclined relative to the bottom portion 35. In particular, the first outer surface 813 and the second outer surface 814 are inclined such that an end (e.g., lower end) adjacent to the bottom portion 35 is more to outside than an end (e.g., upper end) adjacent to the substrate 10, and the end adjacent to the substrate 10 is toward the power component 20. Therefore, the first outer surface 813 and the second outer surface 814 face the lower surface 102 of the substrate 10.

The MOSs 41 and 42 are disposed on the first outer surface 813, and the MOSs 43 and 44 are disposed on the second outer surface 814.

The MOS 41 is disposed on the first outer surface 813 such that the leads 411 are adjacent to the substrate 10, and is fixed to the first outer surface 813 with the MOS-fixing screw 451. The MOS 42 is disposed on the first outer surface 813 such that the leads 421 are adjacent to the substrate 10, and is fixed to the first outer surface 813 with the MOS-fixing screw 452.

The MOSs 41 and 42 are partly disposed outside of the projected area of the substrate 10.

The MOS 43 is disposed on the second outer surface 814 such that the leads 431 are adjacent to the substrate 10, and is fixed to the second outer surface 814 with the MOS-fixing screw 453. The MOS 44 is disposed on the second outer surface 814 such that the leads 441 are adjacent to the substrate 10, and is fixed to the second outer surface 814 with the MOS-fixing screw 454.

The MOSs 43 and 44 are entirely disposed inside of the projected area of the substrate 10. Also, each of the MOSs 43 and 44 is disposed such that a part of the MOSs 43 and 44 is located inside of the projected area of the power region 12 and a remaining part of the MOSs 43 and 44 is located inside of the projected area of the control region 11.

In FIG. 19 and FIG. 20, the MOS 44 is located closer to the connector 19 than the MOS 43. Alternatively, the MOS 43 may be located closer to the connector 19 than the MOS 44. Namely, similar to the first embodiment, the MOSs 41 and 43, which are at the high potential side and generate a relatively large amount of heat, may be located at the ends so that the heat radiating portions are dispersed.

The MOSs 41 to 44 are electrically connected to the substrate 10 through the leads 411, 421, 431, 441, within the power region 12.

Although the MOSs 43 and 44 are partly located within the projected area of the control region 11, the MOSs 43 and 44 are connected to the substrate 10 within the power region 12, as shown in FIG. 20. The MOSs 43 and 44 partly overlap with the IC 16 mounted on the lower surface 102 of the substrate 10 within the projected area. However, a space is provided between the MOSs 43 and 44 and the IC 16. Therefore, it is less likely that the heat generated from the MOSs 43 and 44 will be transferred to the IC 16. The first outer surface 813 and the second outer surface 814 may correspond to the “first surface” and the “surface on which the semiconductor module is disposed”. For example, the first outer surface 813 and the second outer surface 814 may correspond to the “inclined surface inclined relative to the bottom portion 35 and on which the semiconductor module is disposed”

(13) In the present embodiment, the first outer surface 813 and the second outer surface 814 of the heat radiating portion 81 on which the semiconductor modules 41 to 44 are disposed are inclined relative to the bottom portion 35. Therefore, the height of the electronic control unit 71 can be reduced.

Further, the similar effects to the embodiments described above, in particular, the effects similar to (1), (4) and (5) are achieved.

### Twelfth Embodiment

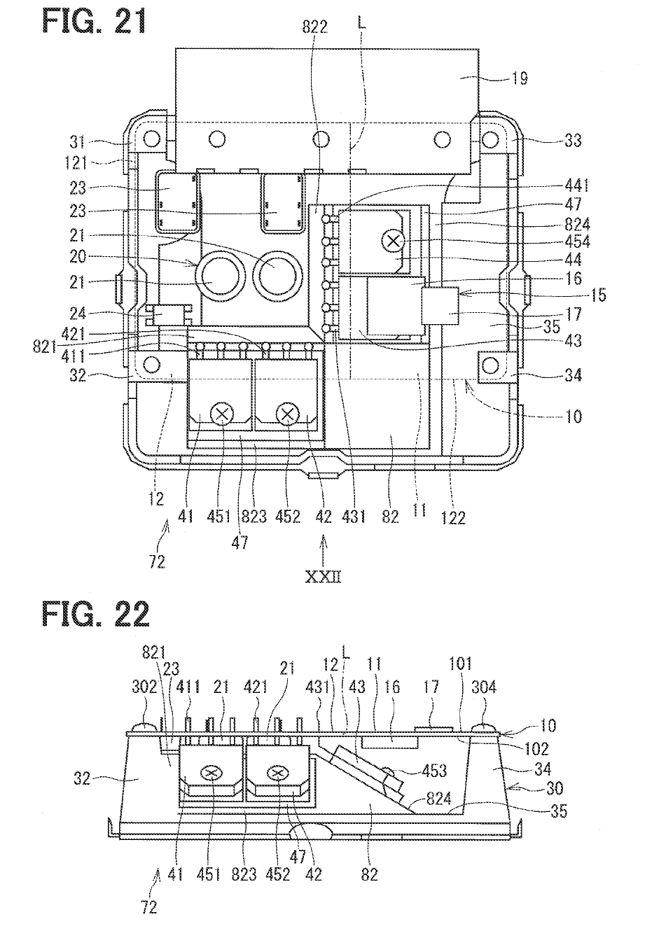

An electronic control unit according to a twelfth embodiment of the present disclosure will be described with reference to FIG. 21 and FIG. 22.

An electronic control unit 72 of the present embodiment is a modification of the eleventh embodiment.

A heat radiating portion 82 of the electronic control unit 72 includes a first heat radiating portion 821 and a second heat radiating portion 822. The first heat radiating portion 821 of the present embodiment is integral with the second substrate-fixing portion 32. Also, it can be understood that the second substrate-fixing portion 32 is disposed at the end of the heat radiating portion 82. The first heat radiating portion 821 of the present embodiment is similar to the first heat radiating portion 811 of the eleventh embodiment, except that the first heat radiating portion 821 is integral with the second substrate-fixing portion 32. Further, the second heat radiating portion 822 is similar to the second heat radiating portion 812 of the eleventh embodiment.

The first heat radiating portion 821 has a first outer surface 823 on a side opposite to the power component 20. The second heat radiating portion 822 has a second outer surface 824 on a side opposite to the power component 20. The first outer surface 823 and the second outer surface 824 are inclined relative to the bottom portion 35, similar to the eleventh embodiment.

Because the arrangement and the like of the MOSs 41 to 44 are similar to those of the eleventh embodiment, the description thereof will be omitted.

Accordingly, the similar effects to the embodiments described above, in particular, the effects similar to (1), (2), (4), (5), (7) and (13) are achieved.

### Thirteenth Embodiment

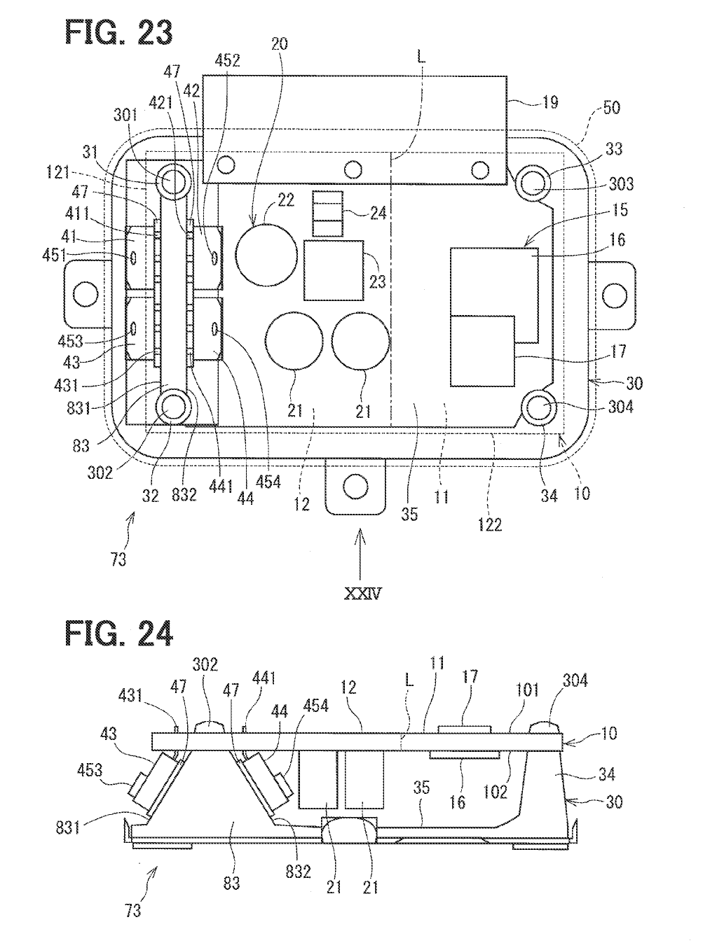

An electronic control unit according to a thirteenth embodiment of the present disclosure will be described with reference to FIG. 23 and FIG. 24.

An electronic control unit 73 of the present embodiment has a heat radiating portion 83. The heat radiating portion 83 is disposed substantially parallel to the side 121 of the substrate 10 adjacent to the power region 12. That is, the heat radiating portion 83 does not have a portion corresponding to the second heat radiating portion of the embodiments described above, and thus has a straight shape. Therefore, the volume of the housing can be reduced, as compared with the embodiments described above.

The heat radiating portion 83 has an outer surface 831 and an inner surface 832. The outer surface 831 and the inner surface 832 are inclined relative to the bottom portion 35. In particular, the outer surface 831 is formed such that an end (e.g., lower end) adjacent to the bottom portion 35 is located more to outside than an end (e.g., upper end) adjacent to the substrate 10, and the end adjacent to the substrate 10 is located more to inside. The inner surface 832 is formed such that an end (e.g., lower end) adjacent to the bottom portion 35 is located more to inside than an end (e.g., upper end) adjacent to the substrate 10, and the end adjacent to the substrate 10 is located more to outside. Therefore, the outer surface 831 and the inner surface 832 face the lower surface 102 of the substrate 10.

In the present embodiment, the upper MOSs 41 and 43, which generate a relatively large amount of heat, are fixed to the outer surface 831 of the heat radiating portion 83 through the heat radiating and insulating sheet 47. The upper MOSs 41 and 43 are partly disposed outside of the projected area of the substrate 10.

Further, the lower MOSs 42 and 44, which generate a relatively small amount of heat, are fixed to the inner surface 832 of the heat radiating portion 83 through the heat-radiating and insulating sheet 47. The lower MOSs 42 and 44 are entirely disposed inside of the projected area of the substrate 10.

Therefore, the heat radiating portion 83 is located between the upper MOSs 41 and 43, which generate a relatively large amount of heat, and the power component 20 such as the aluminum electrolytic capacitor 21. As such, it is less likely that the upper MOSs 41 and 43 will be affected by the heat generated from the power component 20 and the lower MOSs 42 and 44, and thus the heat interference can be reduced.

In the present embodiment, the outer surface 831 and the inner surface 832 may correspond to the “surface on which a semiconductor module is disposed”. For example, the outer surface 831 and the inner surface 832 may correspond to the “inclined surface inclined relative to the bottom portion 35 and on which the semiconductor module is disposed”. Also, the outer surface 831 may correspond to the “first surface”, and the inner surface 832 may correspond to a “second surface”. Further, the MOSs 41 and 43 may correspond to a “first module”, and the MOSs 42 and 44 may correspond to a “second module”.

Accordingly, the similar effects to the embodiments described above, in particular, the effects similar to (1), (2), (4), (7), (9) and (13) are achieved.

### Other Embodiments

(i) In the embodiments described above, the semiconductor module is a MOSFET. In another embodiment, the semiconductor module may any type of module, such as an IGBT (insulated gate bipolar transistor), a transistor, a thyristor.

(ii) In the embodiments described above, four semiconductor modules are employed. In another embodiment, the number of the semiconductor modules is not limited to four, but may be any number.

In the first embodiment and the second embodiment, two semiconductor modules are disposed on the first outer surface of the heat radiating portion, and two semiconductor modules are disposed on the second outer surface of the heat radiating portion. In the third to sixth embodiments, two semiconductor modules are disposed on the outer surface of the heat radiating portion, and two semiconductor modules are disposed on the inner surface of the heat radiating portion. In another embodiment, the arrangement of the semiconductor modules on the heat radiating portion may not be limited to a symmetric arrangement. The semiconductor modules may be disposed on the heat radiating portion in any arrangement. For example, in the examples of the first embodiment and the second embodiment, all the semiconductor modules may be disposed on either the first outer surface or the second outer surface of the heat radiating portion. Alternatively, three semiconductor modules may be disposed on one of the first outer surface or the second outer surface of the heat radiating portion, and one semiconductor module may be disposed on the other of the first outer surface or the second outer surface. Alternatively, a part of the semiconductor modules may be disposed on the inner surface of the heat radiating portion in the first embodiment and the second embodiment. Similarly, in the examples of the third to sixth embodiments, all the semiconductor modules may be disposed on the outer surface of the heat radiating portion. Alternatively, three semiconductor modules may be disposed on one of the first outer surface or the second outer surface of the heat radiating portion, and one semiconductor module may be disposed on the other of the first outer surface or the second outer surface.

(iii) In the first embodiment and the second embodiment, the upper MOSs, which generate a relatively large amount of heat, are disposed at the ends of the heat radiating portion. In another embodiment, the upper MOS may be disposed adjacent to the second substrate-fixing portion. The upper MOSs may be disposed adjacent to the second substrate-fixing portion, and a temperature detecting portion, such as a thermistor, may be disposed between the two upper MOSs, such as at the second substrate-fixing portion. In this case, when the control is performed using the temperature detected by the temperature detecting portion, control characteristics improve.

In the third embodiment to the sixth embodiment described above, the upper MOSs are disposed on the outer surface of the heat radiating portion, and the lower MOSs are disposed on the inner surface of the heat radiating portion. In another embodiment, in order to disperse the heat generating portions, the upper MOSs may be disposed in a dispersed manner such that the upper MOSs are not next to each other and are not opposed to each other.

Further, the arrangement of the semiconductor modules may not be limited to these examples. The semiconductor modules may be disposed in any arrangement.

In the fourth, sixth, eighth and tenth embodiments described above, the MOS on the outer surface and the MOS on the inner surface are located at the opposed positions, and at the opposite sides of the common through hole. In another embodiment, even when the MOS on the outer surface and the MOS on the inner surface are located at the opposed positions, the fixing hole may be formed for each of the MOSs, in place of the through hole.

(iv) In the embodiments described above, the semiconductor modules are fastened to the heat radiating portion with the MOS-fixing screws. In another embodiment, the semiconductor modules may be fixed to the heat radiating portion in any ways. In the embodiments described above, the substrate is fastened to the substrate-fixing portions of the housing with the substrate-fixing screws. In another embodiment, the substrate may be fixed to the substrate-fixing portions of the housing in any ways.

(v) In the embodiments described above, the heat-radiating and insulating sheet is disposed between the semiconductor modules and the heat radiating portion. In another embodiment, a heat radiating gel, a heat radiating grease or the like may be used, in place of the heat-radiating and insulating sheet. Further, a member having one of a function of heat radiation or a function of insulation may be employed. Alternatively, the heat-radiating and insulating sheet may be eliminated. This is similar to the heat-radiating and insulating sheet disposed between the semiconductor modules and the cover member.

(vi) In the embodiments described above, the control component includes the IC and the CPU. In another embodiment, the control component may include any component that is used for control computations of any devices, and generates a relatively small amount of heat.

In the embodiments described above, the power component include the aluminum electrolytic capacitor, the coil, the relay and the shunt resistor. In another embodiment, any type of capacitor may be employed, in place of the aluminum electrolytic capacitor. A part of the power component may be eliminated as long as the power component includes at least one of the capacitor, the coil, the relay, or the resistor. The power component may include any electronic component, other than the capacitor, the coil, the relay, and the resistor.

In the embodiments described above, the CPU is mounted on the upper surface of the substrate, and the other electronic components are mounted on the lower surface of the substrate. In another embodiment, each of the electronic components may be mounted on either the upper surface or the lower surface of the substrate as long as the control component is disposed in the control region and the power component is disposed in the power region.

(vii) In the first embodiment and the second embodiment, the substrate-fixing portions are disposed at the end and the corner of the heat radiating portion. In another embodiment, further another substrate-fixing portion may be provided at the end of the heat radiating portion adjacent to the fourth substrate-fixing portion. In addition to the substrate-fixing portions of the first embodiment to the fifth embodiment described above, the substrate-fixing portion may be formed at a middle portion of the heat radiating portion. Furthermore, in the sixth embodiment, the substrate-fixing portion may be further formed at the end of the heat-radiating and fixing portion.

In addition, the shape of the heat radiating portion may not be limited to the substantially L shape or the straight shape. The heat radiating portion may have any other shape.

(viii) In the eleventh embodiment to the thirteenth embodiment, the surface on which the semiconductor modules are disposed is inclined. In another embodiment, a surface on which the semiconductor module is disposed may be inclined, in a heat radiating portion having any shape, such as the heat radiating portion that has the shape extending along the two sides of the substrate, for example, as the first embodiment.

In the embodiments described above, the surface on which semiconductor module is disposed faces the substrate. In another embodiment, the surface on which the semiconductor module is disposed may face the bottom portion.

Furthermore, also in the case where the heat radiating portion is inclined, the cover member may have a shape according to the shape of the heat radiating portion. In such a case, the semiconductor module may be fixed in the sate of being interposed between the heat radiating portion and the cover member, thereby to also have the back side heat radiation structure.

(ix) In the eleventh embodiment, the heat radiating portion and the substrate-fixing portion are separate parts. In another embodiment, for example, the heat radiating portion and the substrate-fixing portions of the first to sixth embodiments may be provided as separate parts.

(x) In the embodiments described above, the electronic control unit is employed to the electric power steering system. In another embodiment, the use of the electronic control unit is not limited to the electric power steering system, and the electronic control unit may be employed to any device.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. An electronic control unit comprising:
a substrate having a control region and a power region;
a control component being disposed on the control region of the substrate;
a power component being disposed on the power region of the substrate;
a housing having a bottom portion that is opposed to the substrate, a substrate-fixing portion that extends from the bottom portion and to which the substrate is fixed, and a heat radiating portion that extends from the bottom portion; and
a plurality of semiconductor modules being disposed along the heat radiating portion and being electrically connected to the power region of the substrate, wherein
at least one of the semiconductor modules is fixed to a first surface of the heat radiating portion, the first surface being on a side opposite to the power component.

2. The electronic control unit according to claim 1, wherein
the heat radiating portion is integral with the substrate-fixing portion to which the power region of the substrate is fixed.

3. The electronic control unit according to claim 1, wherein
the heat radiating portion has an inclined surface being inclined relative to the bottom portion, and
at least one of the semiconductor modules is disposed on the inclined surface.

4. The electronic control unit according to claim 3, wherein
the inclined surface is at least one of the first surface to which the at least one of the semiconductor modules is fixed or a second surface opposite to the first surface.

5. The electronic control unit according to claim 1, wherein
the heat radiating portion has a perpendicular surface being perpendicular to the bottom portion, and
at least one of the semiconductor modules is disposed on the perpendicular surface.

6. The electronic control unit according to claim 5, wherein
the perpendicular surface is at least one of the first surface to which the at least one of the semiconductor modules is fixed or a second surface opposite to the first surface.

7. The electronic control unit according to claim 1, further comprising:
a cover member accommodating the substrate, the control component, the power component, the heat radiating portion and the semiconductor modules, wherein
the at least one of the semiconductor modules fixed to the first surface is fixed in a state of being interposed between the heat radiating portion and the cover member.

8. The electronic control unit according to claim 1, wherein
the heat radiating portion includes a first heat radiating portion and a second heat radiating portion, the first heat radiating portion being disposed substantially parallel to a first side of the substrate, and the second heat radiating portion being disposed substantially parallel to a second side of the substrate.

9. The electronic control unit according to claim 1, wherein
the heat radiating portion is disposed substantially parallel to one side of the substrate.

10. The electronic control unit according to claim 1, wherein
all of the semiconductor modules are fixed to the first surface of the heat radiating portion.

11. The electronic control unit according to claim 1, wherein
the heat radiating portion has a second surface opposite to the first surface and adjacent to the power component,
the at least one of the semiconductor modules fixed to the first surface is referred to as a first module, and
at least another one of the semiconductor modules is fixed to the second surface of the heat radiating portion, and is referred to as a second module.

12. The electronic control unit according to claim 11, wherein
the first module is disposed at a position opposite to the second module through the heat radiating portion.

13. The electronic control unit according to claim 12, wherein
the first module and the second module are fixed at opposite ends of a through hole that passes through the heat radiating portion from the first surface and the second surface.

14. The electronic control unit according to claim 11, wherein
the first module and the second module are disposed at offset positions from each other through the heat radiating portion.

15. The electronic control unit according to claim 1, wherein
the substrate-fixing portion to which the power region of the substrate is fixed is disposed at one of an end or a corner of the heat radiating portion.

16. The electronic control unit according to claim 1, wherein
the substrate-fixing portion to which the power region of the substrate is fixed is disposed at a middle of the heat radiating portion.

17. The electronic control unit according to claim 1, wherein
the plurality of semiconductor modules are bridge-connected, and
the at least one of the semiconductor modules fixed to the first surface of the heat radiating portion is a high potential-side module disposed on a high potential side in a bridge connection.
